(19) United States
(12) Patent Application Publication
(10) Pub. No.: US 2025/0240990 A1
(43) Pub. Date: Jul. 24, 2025

(54) BIPOLAR JUNCTION TRANSISTOR DEVICE AND FABRICATION METHOD THEREOF

(71) Applicant: UNITED MICROELECTRONICS CORP., Hsin-Chu City (TW)

(72) Inventors: Hsin-Han Wu, Hsinchu City (TW); Kai-Kuen Chang, Hsinchu City (TW); Ping-Hung Chiang, Tainan City (TW); Ta-Wei Chiu, Changhua County (TW)

(73) Assignee: UNITED MICROELECTRONICS CORP., Hsin-Chu City (TW)

(21) Appl. No.: 18/587,890

(22) Filed: Feb. 26, 2024

(30) Foreign Application Priority Data
Jan. 24, 2024 (TW) 113102694

(51) Int. Cl. H01L 29/735; H01L 21/285; H01L 29/45; H01L 29/66

(52) U.S. Cl. CPC H10D 10/60; H01L 21/28518; H10D 10/061; H10D 64/62

(57) ABSTRACT

A BJT device includes a substrate of first conductive type; a first ion well of second conductive type located in the substrate; a second ion well of first conductive type located in the first ion well; an emitter region of second conductive type located in the second ion well; a first trench isolation region surrounding the emitter region; a base region of first conductivity type located in the second ion well; a second trench isolation region surrounding the base region; a third ion well of second conductivity type located in the first ion well and surrounding the second ion well; and a collector region of second conductivity type located in the third ion well and surrounding the second trench isolation region. The junction depth of the emitter region is deeper than the junction depth of the base region or the junction depth of the collector region.

### BACKGROUND OF THE INVENTION

### 1. Field of the Invention

The present invention relates to the field of semiconductor technology, and in particular, to an improved bipolar junction transistor (BJT) device and a manufacturing method thereof.

### 2. Description of the Prior Art

BJT devices are typically used as an amplifying device or a switching device applied in a semiconductor integrated circuit (IC). A BJT device is composed of three doped active regions including an emitter region, a base region and a collector region. These regions form a first diode between the base region and the emitter region and a second diode between the base region and collector region.

In the current semiconductor high-voltage process, large-area low-voltage NPN BJT devices are prone to mismatch problems. Therefore, this technical field still needs an improved BJT device and its manufacturing method.

### SUMMARY OF THE INVENTION

It is one object of the present invention to provide an improved bipolar junction transistor (BJT) device and a manufacturing method thereof to solve the deficiencies or shortcomings of the existing technology.

One aspect of the invention provides a bipolar junction transistor (BJT) device including a substrate of a first conductivity type; a first ion well of a second conductivity type disposed in the substrate, wherein the second conductivity is opposite to the first conductivity type; a second ion well of the first conductivity type disposed in the first ion well; an emitter region of the second conductivity type disposed in the second ion well; a first trench isolation region surrounding the emitter region; a base region of the first conductivity type disposed in the second ion well, wherein the base region surrounds the first trench isolation region; a second trench isolation region surrounding the base region; a third ion well of the second conductivity type disposed in the first ion well and around the second ion well; and a collector region of the second conductivity type disposed in the third ion well and surrounding the second trench isolation region. A junction depth of the emitter region is deeper than a junction depth of the base region or a junction depth of the collector region.

According to some embodiments, the emitter region has a doping concentration that is greater than a doping concentration of the collector region.

According to some embodiments, the BJT device further includes an emitter salicide layer disposed on the emitter region; a base salicide layer disposed on the base region; and a collector salicide layer disposed on the collector region.

According to some embodiments, the emitter salicide layer has a top surface that is lower than a top surface of the base salicide layer and a top surface of the collector salicide layer.

According to some embodiments, the emitter salicide layer, the base salicide layer, and the collector salicide layer comprise cobalt silicide or nickel silicide.

According to some embodiments, the BJT device further includes a recessed region between the top surface of the emitter salicide layer and the first trench isolation region.

According to some embodiments, the BJT device further includes a dielectric layer disposed on the substrate, wherein the dielectric layer covers the emitter region, the base region, and the collector region; an emitter contact disposed in the dielectric layer, wherein the emitter contact is electrically connected to the emitter salicide layer; a base contact disposed in the dielectric layer, wherein the base contact is electrically connected to the base salicide layer; and a collector contact disposed in the dielectric layer, wherein the collector contact is electrically connected to the collector salicide layer.

According to some embodiments, the emitter contact, the base contact, and the collector contact comprise tungsten.

According to some embodiments, the first conductivity type is P type and the second conductivity type is N type.

According to some embodiments, the substrate comprises a silicon substrate.

Another aspect of the invention provides a method for forming a bipolar junction transistor (BJT) device. A substrate of a first conductivity type is provided. A first ion well of a second conductivity type is formed in the substrate. The second conductivity is opposite to the first conductivity type. A second ion well of the first conductivity type is formed in the first ion well. An emitter region of the second conductivity type is formed in the second ion well. A first trench isolation region is formed to surround the emitter region. A base region of the first conductivity type is formed in the second ion well. The base region surrounds the first trench isolation region. A second trench isolation region is formed to surround the base region. A third ion well of the second conductivity type is formed in the first ion well and around the second ion well. A collector region of the second conductivity type is formed in the third ion well and surrounds the second trench isolation region. A junction depth of the emitter region is deeper than a junction depth of the base region or a junction depth of the collector region.

According to some embodiments, the emitter region has a doping concentration that is greater than a doping concentration of the collector region.

According to some embodiments, the method further includes the steps of: forming an emitter salicide layer on the emitter region; forming a base salicide layer on the base region; and forming a collector salicide layer on the collector region.

According to some embodiments, the emitter salicide layer has a top surface that is lower than a top surface of the base salicide layer and a top surface of the collector salicide layer.

According to some embodiments, the emitter salicide layer, the base salicide layer, and the collector salicide layer comprise cobalt silicide or nickel silicide.

According to some embodiments, the method further includes the step of: forming a recessed region between the top surface of the emitter salicide layer and the first trench isolation region.

According to some embodiments, the method further includes the steps of: forming a dielectric layer on the substrate, wherein the dielectric layer covers the emitter region, the base region, and the collector region; forming an emitter contact in the dielectric layer, wherein the emitter contact is electrically connected to the emitter salicide layer; forming a base contact in the dielectric layer, wherein the base contact is electrically connected to the base salicide layer; and forming a collector contact in the dielectric layer, wherein the collector contact is electrically connected to the collector salicide layer.

According to some embodiments, the emitter contact, the base contact, and the collector contact comprise tungsten.

According to some embodiments, the first conductivity type is P type and the second conductivity type is N type.

According to some embodiments, the substrate comprises a silicon substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic top view of a semiconductor device according to an embodiment of the present invention.

FIG. 2 is a schematic cross-sectional view taken along line I-I′ in FIG. 1

FIG. 3 to FIG. 5 are schematic diagrams showing a method of forming a bipolar junction transistor (BJT) device according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

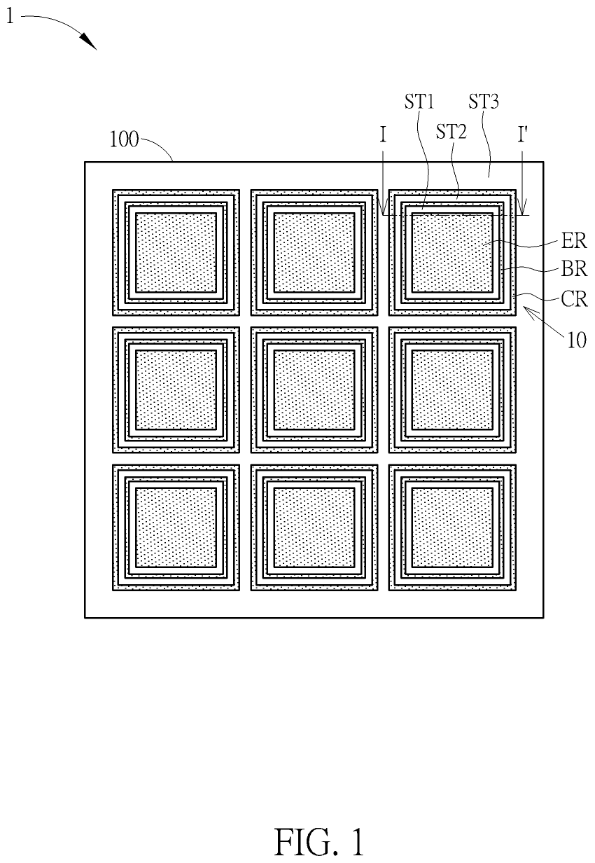

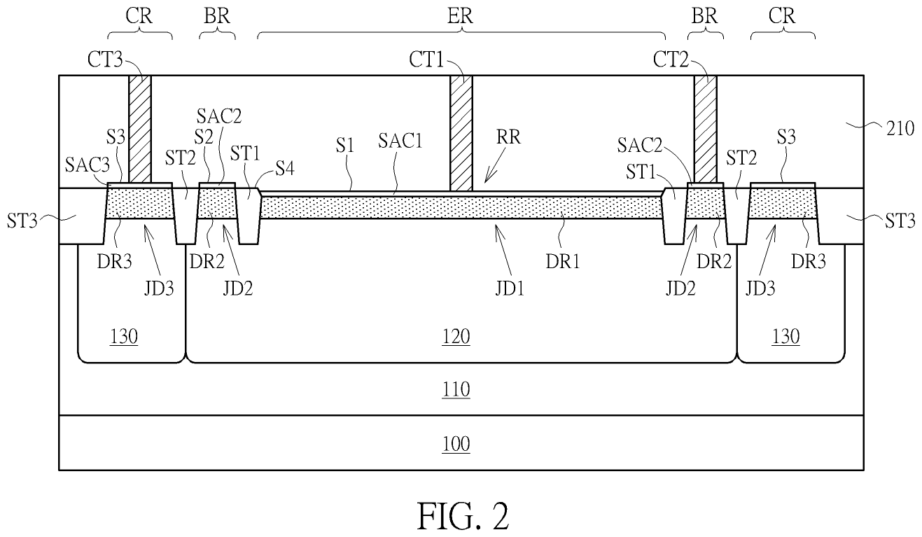

Please refer to FIG. 1 and FIG. 2, wherein FIG. 1 is a schematic top view of a semiconductor device according to an embodiment of the present invention, and FIG. 2 is a schematic cross-sectional view taken along line I-I′ in FIG. 1. As shown in FIG. 1 and FIG. 2, the semiconductor device 1 includes a substrate 100, such as, but not limited to, a silicon substrate. According to an embodiment of the present invention, the substrate 100 has a first conductivity type, for example, P type. A plurality of bipolar junction transistor (BJT) devices 10 are formed in the substrate 100. According to an embodiment of the present invention, for example, the plurality of BJT devices 10 in FIG. 1 may be arranged in a 3×3 array, but is not limited thereto. Those skilled in the art should understand that the number, arrangement and size of the plurality of BJT devices 10 in the figure are only for illustration purposes. According to an embodiment of the present invention, each BJT device 10 includes a central emitter region ER, an annular base region BR surrounding the emitter region ER, and an annular collector region CR surrounding the base region BR and the emitter region ER.

As shown in FIG. 2, a first ion well 110 of a second conductivity type is provided in the substrate 100. The second conductivity type is opposite to the first conductivity type. For example, the second conductivity type is N-type, and the first ion well 110 is a deep N-type well. According to an embodiment of the present invention, a second ion well 120 of the first conductivity type is provided in the first ion well 110. For example, the first conductivity type is P-type, and the second ion well 120 is a P-type well. According to an embodiment of the present invention, the emitter region ER of the second conductivity type and the base region BR of the first conductivity type are located in the second ion well 120.

According to an embodiment of the present invention, each BJT device 10 further includes an annular first trench isolation region ST1 surrounding the emitter region ER. The base region BR surrounds the first trench isolation region ST1. According to an embodiment of the present invention, each BJT device 10 further includes an annular second trench isolation region ST2 surrounding the base region BR. According to an embodiment of the present invention, each BJT device 10 further includes an annular third trench isolation region ST3 surrounding the collector region CR.

According to an embodiment of the present invention, each BJT device 10 further includes a third ion well 130 of the second conductivity type, located in the first ion well 110 and surrounding the second ion well 120. According to an embodiment of the present invention, collector region ER of the second conductivity type is located in the third ion well 130 and surrounds the second trench isolation region ST2. According to an embodiment of the present invention, the emitter region ER includes a heavily doped region DR1 of the second conductivity type, the base region BR includes a heavily doped region DR2 of the first conductivity type, and the collector region CR includes a heavily doped region DR3 of the second conductivity type. According to an embodiment of the present invention, for example, the heavily doped region DR1 may be a medium-voltage N⁺ doped region, the heavily doped region DR2 may be a low-voltage P⁺ doped region, and the heavily doped region DR3 may be a low-voltage N⁺ doped region.

According to an embodiment of the present invention, the junction depth JD1 of the heavily doped region DR1 in the emitter region ER is deeper than the junction depth JD2 of the heavily doped region DR2 in the base region BR or the junction depth JD3 of the heavily doped region DR3 in the collector region CR. According to an embodiment of the present invention, the doping concentration of the heavily doped region DR1 in the emitter region ER is greater than the doping concentration of the heavily doped region DR3 in the collector region CR.

According to an embodiment of the present invention, each BJT device 10 further includes an emitter salicide layer SAC1 disposed on the emitter region ER; a base salicide layer SAC2 disposed on the base region BR; and a collector salicide layer SAC3 disposed on the collector region CR. According to an embodiment of the present invention, the top surface S1 of the emitter salicide layer SAC1 may be lower than the top surface S2 of the base salicide layer SAC2 and the top surface S3 of the collector salicide layer SAC3. According to an embodiment of the present invention, the top surface S1 of the emitter salicide layer SAC1 is lower than the top surface S4 of the first trench isolation region ST1. According to an embodiment of the present invention, the emitter salicide layer SAC1, the base salicide layer SAC2, and the collector salicide layer SAC3 may include cobalt silicide or nickel silicide, but are not limited thereto.

According to an embodiment of the present invention, each BJT device 10 further includes a recessed region RR located between the top surface S1 of the emitter salicide layer and the first trench isolation region ST1. More specifically, the recessed region RR is located between the top surface S1 of the emitter salicide layer and the upper sidewall of the first trench isolation region ST1.

According to an embodiment of the present invention, each BJT device 10 further includes a dielectric layer 210 located on the substrate 100. The dielectric layer 210 covers the emitter region ER, the base region BR and the collector region CR. According to an embodiment of the present invention, the dielectric layer 210 may be, for example, a silicon oxide layer or a low dielectric constant material layer, but is not limited thereto. According to an embodiment of the present invention, each BJT device 10 further includes an emitter contact CT1 located in the dielectric layer 210 and electrically connected to the emitter salicide layer SAC1; a base contact CT2 located in the dielectric layer 210 and electrically connected to the base salicide layer SAC2; and a collector contact CT3 located in the dielectric layer 210 and electrically connected to the collector salicide layer SAC3. According to an embodiment of the present invention, for example, the emitter contact CT1, the base contact CT2, and the collector contact CT3 may include tungsten.

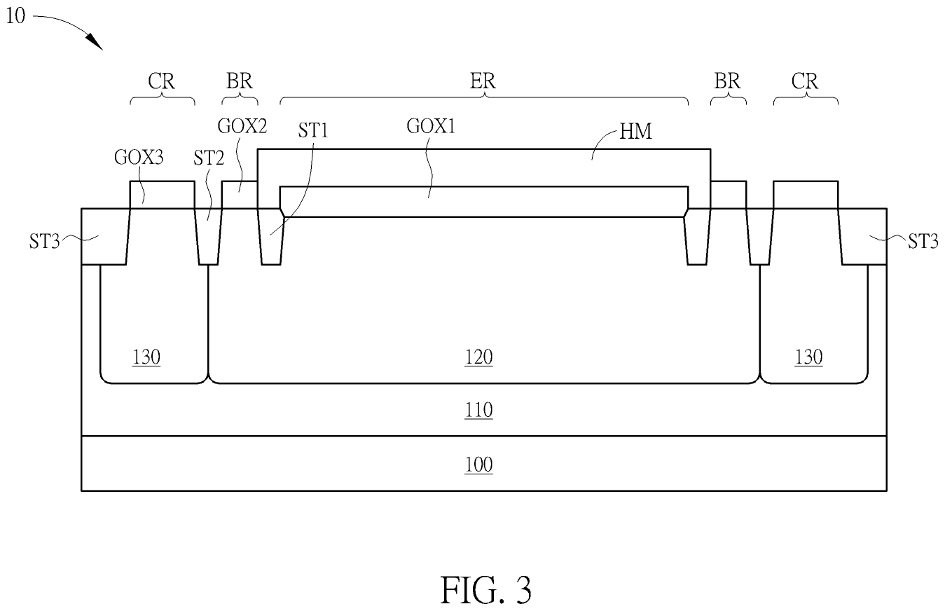

Please refer to FIG. 3 to FIG. 5, which are schematic diagrams showing a method of forming a bipolar junction transistor (BJT) device according to an embodiment of the present invention. As shown in FIG. 3, the BJT device 10 is formed on a substrate 100, such as a silicon substrate. According to an embodiment of the present invention, the substrate 100 has a first conductivity type, for example, P type. A first ion well 110 of a second conductivity type is formed in the substrate 100. The second conductivity type is, for example, N type. Next, a second ion well 120 of the first conductivity type, for example, a P-type well, is formed in the first ion well 110, and a third ion well 120 of the second conductivity type, for example, an N-type well is formed in the first ion well 110 and around the second ion well 120.

According to an embodiment of the present invention, the BJT device 10 includes a central emitter region ER, an annular base region BR surrounding the emitter region ER, and an annular collector region CR surrounding the base region BR and the emitter region ER. After the second ion well 120 and the third ion well 130 are formed, a shallow trench isolation (STI) process is performed to form a first trench isolation region ST1 surrounding the emitter region ER, a second trench isolation region ST2 surrounding the base region BR, and a third trench isolation region ST3 surrounding the collector region CR.

Subsequently, an oxidation process is performed to form a thick silicon oxide layer GOX1, a thick silicon oxide layer GOX2, and a thick silicon oxide layer GOX3 on the substrate 100 in the emitter region ER, the base region BR, and the collector region CR, respectively. The thicknesses of the thick silicon oxide layer GOX1, the thick silicon oxide layer GOX2 and the thick silicon oxide layer GOX3 are equal to the thickness of the gate oxide layer of the medium-voltage device. Next, an etching mask HM, such as a photoresist pattern, is formed on the emitter region ER. The etching mask HM covers the thick silicon oxide layer GOX1, but exposes the thick silicon oxide layer GOX2 and the thick silicon oxide layer GOX3. According to an embodiment of the present invention, the etching mask HM may also cover the first trench isolation region ST1 surrounding the emitter region ER.

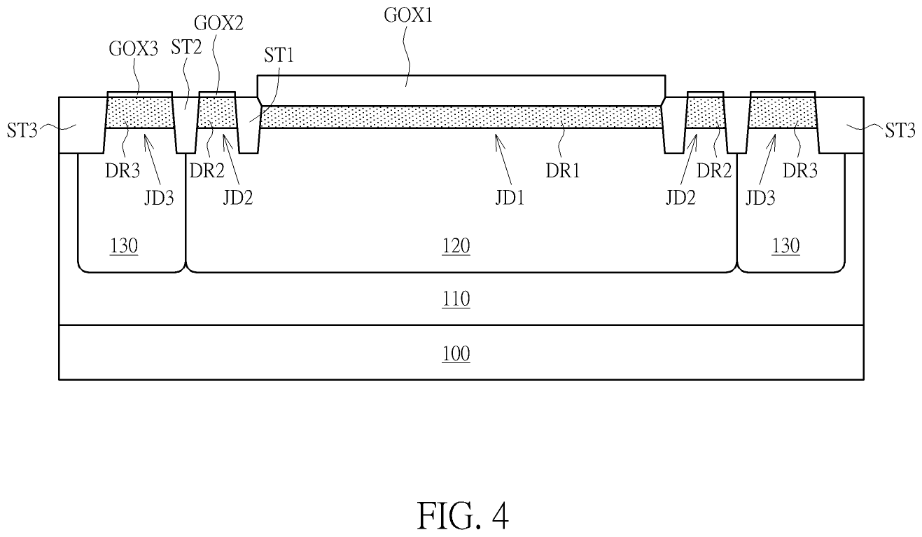

As shown in FIG. 4, an etching process is then performed, for example, a dry etching process, to etch the thick silicon oxide layer GOX2 and the thick silicon oxide layer GOX3 that are not covered by the etching mask HM, thereby forming a screen silicon oxide layer GOS1, a screen silicon oxide layer GOS2 and a screen silicon oxide layer GOS3 with different thicknesses respectively in the emitter region ER, the base region BR and the collector region CR.
Subsequently, multiple ion implantation processes are carried out, and various dopants are implanted into the substrate 100 within the emitter region ER, the base region BR and the collector region CR through the screen silicon oxide layer GOS1, the screen silicon oxide layer GOS2 and the screen silicon oxide layer GOS3, respectively, thereby forming a heavily doped region DR1 of the second conductivity type, a heavily doped region DR2 of the first conductivity type and a heavily doped region DR3 of the second conductivity type. According to an embodiment of the present invention, for example, the heavily doped region DR1 may be a medium-voltage N⁺ doped region, the heavily doped region DR2 may be a low-voltage P⁺ doped region, and the heavily doped region DR3 may be a low-voltage N⁺ doped region.

According to an embodiment of the present invention, the junction depth JD1 of the heavily doped region DR1 in the emitter region ER is deeper than the junction depth JD2 of the heavily doped region DR2 in the base region BR or the junction depth JD3 of the heavily doped region DR3 in the collector region CR. According to an embodiment of the present invention, the doping concentration of the heavily doped region DR1 in the emitter region ER is greater than the doping concentration of the heavily doped region DR3 in the collector region CR.

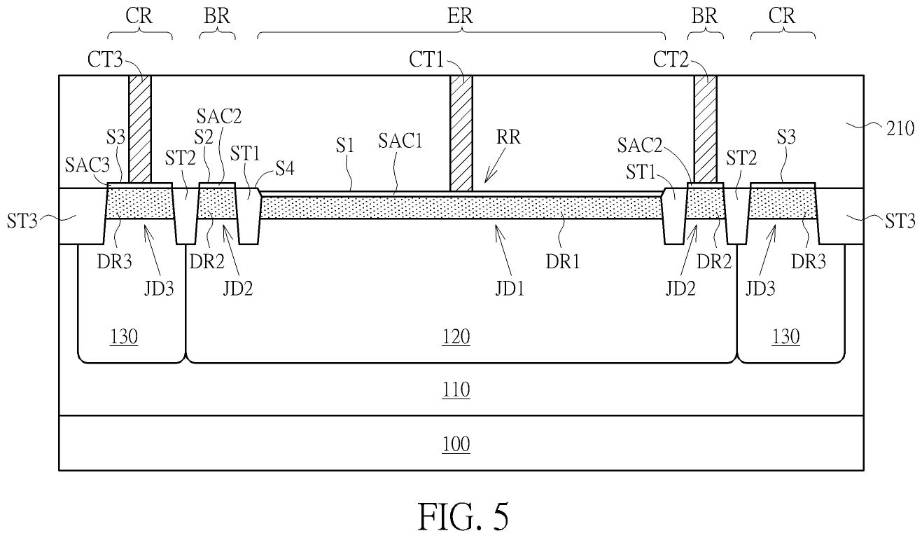

As shown in FIG. 5, the screen silicon oxide layer GOS1, the screen silicon oxide layer GOS2, and the screen silicon oxide layer GOS3 are then removed, and a recessed region RR is formed between the top surface of the emitter region ER and the first trench isolation region ST1. Subsequently, a self-aligned silicide process is performed to form an emitter salicide layer SAC1 on the emitter region ER; a base salicide layer SAC2 on the base region BR; and a collector salicide layer SAC3 on the collector region CR. According to an embodiment of the present invention, the top surface of the emitter salicide layer SAC1 is lower than the top surface of the base salicide layer SAC2 and the top surface of the collector salicide layer SAC3. According to an embodiment of the present invention, the emitter salicide layer SAC1, the base salicide layer SAC2, and the collector salicide layer SAC3 may include, for example, cobalt silicide or nickel silicide.

Subsequently, a chemical vapor deposition (CVD) process is performed to form a dielectric layer 210 on the substrate 100 so that the dielectric layer 210 covers the emitter region ER, the base region BR, and the collector region CR. Finally, emitter contact CT1, base contact CT2 and collector contact CT3 are respectively formed in the dielectric layer 210 and are electrically connected to the emitter salicide layer SAC1, base salicide layer SAC2 and collector salicide layer SAC3, respectively. According to an embodiment of the present invention, the emitter contact SAC1, the base contact SAC2 and the collector contact SAC3 may include, for example, tungsten.

One advantage of the present disclosure is that when performing the ion implantation process of the heavily doped region DR1 in the emitter region ER, a thicker screen silicon oxide layer GOS1 is retained on the emitter region ER. The mismatch problem encountered by large-area, low-voltage NPN BJT devices during the semiconductor high-voltage processes can be alleviated or avoided. In addition, by forming a heavily doped region DR1 with a relatively higher doping concentration in the emitter region ER, such as a medium-voltage N⁺ doped region, the Delta beta value of the BJT device 10 can be improved and the device performance can be enhanced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bipolar junction transistor (BJT) device, comprising:
a substrate of a first conductivity type;
a first ion well of a second conductivity type disposed in the substrate, wherein the second conductivity is opposite to the first conductivity type;
a second ion well of the first conductivity type disposed in the first ion well;
an emitter region of the second conductivity type disposed in the second ion well;
a first trench isolation region surrounding the emitter region;
a base region of the first conductivity type disposed in the second ion well, wherein the base region surrounds the first trench isolation region;
a second trench isolation region surrounding the base region;
a third ion well of the second conductivity type disposed in the first ion well and around the second ion well; and
a collector region of the second conductivity type disposed in the third ion well and surrounding the second trench isolation region, wherein a junction depth of the emitter region is deeper than a junction depth of the base region or a junction depth of the collector region.

2. The BJT device according to claim 1, wherein the emitter region has a doping concentration that is greater than a doping concentration of the collector region.

3. The BJT device according to claim 1 further comprising:
an emitter salicide layer disposed on the emitter region;
a base salicide layer disposed on the base region; and
a collector salicide layer disposed on the collector region.

4. The BJT device according to claim 3, wherein the emitter salicide layer has a top surface that is lower than a top surface of the base salicide layer and a top surface of the collector salicide layer.

5. The BJT device according to claim 4, wherein the emitter salicide layer, the base salicide layer, and the collector salicide layer comprise cobalt silicide or nickel silicide.

6. The BJT device according to claim 4 further comprising:
a recessed region between the top surface of the emitter salicide layer and the first trench isolation region.

7. The BJT device according to claim 1 further comprising:
a dielectric layer disposed on the substrate, wherein the dielectric layer covers the emitter region, the base region, and the collector region;
an emitter contact disposed in the dielectric layer, wherein the emitter contact is electrically connected to the emitter salicide layer;
a base contact disposed in the dielectric layer, wherein the base contact is electrically connected to the base salicide layer; and
a collector contact disposed in the dielectric layer, wherein the collector contact is electrically connected to the collector salicide layer.

8. The BJT device according to claim 7, wherein the emitter contact, the base contact, and the collector contact comprise tungsten.

9. The BJT device according to claim 1, wherein the first conductivity type is P type and the second conductivity type is N type.

10. The BJT device according to claim 1, wherein the substrate comprises a silicon substrate.

11. A method for forming a bipolar junction transistor (BJT) device, comprising:
providing a substrate of a first conductivity type;
forming a first ion well of a second conductivity type in the substrate, wherein the second conductivity is opposite to the first conductivity type;
forming a second ion well of the first conductivity type in the first ion well;
forming an emitter region of the second conductivity type in the second ion well;
forming a first trench isolation region surrounding the emitter region;
forming a base region of the first conductivity type in the second ion well, wherein the base region surrounds the first trench isolation region;
forming a second trench isolation region surrounding the base region;
forming a third ion well of the second conductivity type in the first ion well and around the second ion well; and
forming a collector region of the second conductivity type in the third ion well and surrounding the second trench isolation region, wherein a junction depth of the emitter region is deeper than a junction depth of the base region or a junction depth of the collector region.

12. The method according to claim 11, wherein the emitter region has a doping concentration that is greater than a doping concentration of the collector region.

13. The method according to claim 11 further comprising:
forming an emitter salicide layer on the emitter region;
forming a base salicide layer on the base region; and
forming a collector salicide layer on the collector region.

14. The method according to claim 13, wherein the emitter salicide layer has a top surface that is lower than a top surface of the base salicide layer and a top surface of the collector salicide layer.

15. The method according to claim 14, wherein the emitter salicide layer, the base salicide layer, and the collector salicide layer comprise cobalt silicide or nickel silicide.

16. The method according to claim 14 further comprising:
forming a recessed region between the top surface of the emitter salicide layer and the first trench isolation region.

17. The method according to claim 11 further comprising:
forming a dielectric layer on the substrate, wherein the dielectric layer covers the emitter region, the base region, and the collector region;
forming an emitter contact in the dielectric layer, wherein the emitter contact is electrically connected to the emitter salicide layer;
forming a base contact in the dielectric layer, wherein the base contact is electrically connected to the base salicide layer; and
forming a collector contact in the dielectric layer, wherein the collector contact is electrically connected to the collector salicide layer.

18. The method according to claim 17, wherein the emitter contact, the base contact, and the collector contact comprise tungsten.

19. The method according to claim 11, wherein the first conductivity type is P type and the second conductivity type is N type.

20. The method according to claim 11, wherein the substrate comprises a silicon substrate.
